(19) United States
(12) Patent Application Publication
(10) Pub. No.: US 2013/0312933 A1
(43) Pub. Date: Nov. 28, 2013

(54) Coldplate for Use in an Electric Vehicle (EV) or a Hybrid-Electric Vehicle (HEV)

(71) Applicant: LEAR CORPORATION, Southfield, MI (US)

(72) Inventor: Nadir Sharaf, Bloomfield Township, MI (US)

(73) Assignee: LEAR CORPORATION, Southfield, MI (US)

(21) Appl. No.: 13/686,213

(22) Filed: Nov. 27, 2012

Related U.S. Application Data
(63) Continuation-in-part of application No. 13/477,652, filed on May 22, 2012.

(51) Int. Cl. H05K 7/20

(52) U.S. Cl. CPC H05K 7/20254
USPC 165/80.4

(57) ABSTRACT

A coldplate for use with electronic components in an electric vehicle (EV) or a hybrid-electric vehicle (HEV). The coldplate includes a first portion configured for attachment to a printed circuit board having a plurality of electronic components thereon, and a second portion configured for attachment to the first portion. The first and second portions are further configured to together define a manifold therebetween. The manifold has an inlet, an outlet and a substantially constant height to facilitate a substantially uniform flow of a coolant therethrough for use in dissipating heat generated by the electronic components.

### CROSS-REFERENCE TO RELATED APPLICATION

This application is a continuation-in-part of U.S. patent application Ser. No. 13/477,652 filed on May 22, 2012 (Atty. Docket No. LEAR 51028 PUS), the disclosure of which is incorporated herein by reference in its entirety.

### TECHNICAL FIELD

The following relates to a coldplate for use in an electric vehicle (EV) or a hybrid-electric vehicle (HEV).

### BACKGROUND

Automotive vehicles powered by an electric motor or an electric motor and a gasoline engine are commonly referred to as electric vehicles (EV) or hybrid-electric vehicles (HEV). As is well known in the art, such vehicles include batteries for supplying power to the electric motors thereof.

Electric and hybrid-electric vehicles typically provide for charging such batteries using an interface configured to rectify electrical power from a 120 volt or 240 volt alternating current (AC) utility power line for storage by the vehicle batteries. EVs and HEVs also include an inverter for use in converting the direct current (DC) voltage provided by the vehicle batteries to an AC voltage for use in powering the electric motor or motors of the vehicle. Such an inverter may comprise switching modules and a DC link capacitor.

In addition, electric and hybrid-electric vehicles may also include an auxiliary power module. Such a power module may comprise a number of electronic components, which may include transformers, capacitors, bus bars, metal-oxide-semiconductor field-effect transistors (MOSFETs) and other components.

The components of such an auxiliary power module generate heat as a result of their operations. The heat generated as a result of such operations should be dissipated so that the power module may continue to operate efficiently. Such heat generated by the operation of the power modules components may be dissipated using a coldplate provided as part of the module.

In that regard, an exemplary power converter for use in electric or hybrid-electric vehicles is shown in U.S. Pat. No. 7,974,101 entitled “Power Converter.” Exemplary heat dissipating devices, as well as various features thereof, are shown in U.S. Pat. No. 7,864,506 entitled “System And Method Of Film Capacitor Cooling,” U.S. Pat. No. 7,164,584 entitled “Modular Heat Sink, Electromagnetic Device Incorporating A Modular Heat Sink, And Method Of Cooling An Electromagnetic Device Using A Modular Heat Sink,” U.S. Pat. No. 6,529,394 entitled “Inverter For An Electric Motor,” U.S. Pat. No. 6,466,441 entitled “Cooling Device Of Electronic Part Having High And Low Heat Generating Elements,” U.S. Pat. No. 6,031,751 entitled “Small Volume Heat Sink/Electronic Assembly,” U.S. Patent Application Publication No. 2010/0081191 entitled “Anisotropic Heat Spreader For Use With A Thermoelectric Device,” and U.S. Patent Application Publication No. 2010/0078807 entitled “Power Semiconductor Module Assembly With Heat Dissipating Element.”

However, due to the heat generated as a result of the operation of auxiliary power modules used in an EV or HEV, there exists a need for additional heat dissipation beyond that which may be provided by standard coldplates currently in use with an EV or HEV auxiliary power module. Such a coldplate would include a manifold or chamber for coolant flow through the coldplate, where the manifold or chamber is adapted to provide substantially uniform coolant flow through the coldplate to facilitate dissipating heat generated by electronic components.

### SUMMARY

According to one embodiment disclosed herein, a coldplate is provided for use with electronic components in an electric vehicle (EV) or a hybrid-electric vehicle (HEV). The coldplate comprises a first portion configured for attachment to a printed circuit board having a plurality of electronic components thereon, and a second portion configured for attachment to the first portion. The first and second portions are further configured to together define a manifold therebetween. The manifold has an inlet, an outlet and a substantially constant height to facilitate a substantially uniform flow of a coolant therethrough for use in dissipating heat generated by the electronic components.

According to another embodiment disclosed herein, a heat sink is provided for use with electronic components in an electric vehicle (EV) or a hybrid-electric vehicle (HEV). The heat sink comprises a first portion configured for attachment to a printed circuit board having a plurality of electronic components thereon, and a second portion configured for attachment to the first portion. The first and second portions are further configured to together define a chamber therebetween. The attached first and second portions have a substantially uniform cross section to facilitate a substantially uniform flow of a coolant through the chamber for use in dissipating heat generated by the electronic components.

According to a further embodiment disclosed herein, a heat sink is provided for use with electronic components in an electric vehicle (EV) or a hybrid-electric vehicle (HEV). The heat sink comprises a first portion comprising a substantially plate-like member and configured for attachment to a printed circuit board having a plurality of electronic components thereon, and a second portion comprising a substantially plate-like member and configured for attachment to the first portion. The first and second portions are further configured to together define a chamber therebetween. The chamber has a substantially constant height to facilitate a substantially uniform flow of a coolant therethrough for use in dissipating heat generated by the electronic components.

A detailed description of these embodiments of a coldplate for use in an electric vehicle (EV) or a hybrid-electric vehicle (HEV) are set forth below together with accompanying drawings.

### BRIEF DESCRIPTION OF THE DRAWINGS

FIGS. 1A and 1B are perspective views of a coldplate for use in an electric vehicle (EV) or a hybrid-electric vehicle (HEV) as disclosed herein;

FIG. 2 is an exploded view of the coldplate of FIGS. 1A and 1B for use in an EV or HEV as disclosed herein;

FIGS. 3A and 3B are cross-sectional views of the coldplate of FIGS. 1A and 1B, taken along the lines 3A/3B-3A/3B; and

FIGS. 4A and 4B are cross-sectional views of the coldplate of FIGS. 1A and 1B, taken along lines 4A/4B-4A/4B.

### DETAILED DESCRIPTION

With reference to the Figures, a more detailed description of embodiments of a coldplate for use in an electric vehicle (EV) or a hybrid-electric vehicle (HEV) will be described. For ease of illustration and to facilitate understanding, like reference numerals have been used herein for like components and features throughout the drawings.

As noted above, electric and hybrid-electric vehicles may include an auxiliary power module. Such a power module may comprise a number of electronic components, which may include transformers, capacitors, bus bars, metal-oxide-semiconductor field-effect transistors (MOSFETs) and other components.

The components of such an auxiliary power module generate heat as a result of their operations. The heat generated as a result of such operations should be dissipated so that the power module may continue to operate efficiently. Such heat generated by the operation of the power modules components may be dissipated using a coldplate provided as part of the module.

Exemplary heat dissipating devices, as well as various features thereof, are shown in U.S. Pat. No. 7,864,506 entitled “System And Method Of Film Capacitor Cooling,” U.S. Pat. No. 7,164,584 entitled “Modular Heat Sink, Electromagnetic Device Incorporating A Modular Heat Sink, And Method Of Cooling An Electromagnetic Device Using A Modular Heat Sink,” U.S. Pat. No. 6,529,394 entitled “Inverter For An Electric Motor,” U.S. Pat. No. 6,466,441 entitled “Cooling Device Of Electronic Part Having High And Low Heat Generating Elements,” U.S. Pat. No. 6,031,751 entitled “Small Volume Heat Sink/Electronic Assembly,” U.S. Patent Application Publication No. 2010/0081191 entitled “Anisotropic Heat Spreader For Use With A Thermoelectric Device,” and U.S. Patent Application Publication No. 2010/0078807 entitled “Power Semiconductor Module Assembly With Heat Dissipating Element.”

There exists a need, however, for additional heat dissipation beyond that which may be provided by standard coldplates currently in use with an EV or HEV auxiliary power module. Such a coldplate would include a manifold or chamber for coolant flow through the coldplate, where the manifold or chamber is adapted to provide substantially uniform coolant flow through the coldplate to facilitate dissipating heat generated by electronic components.

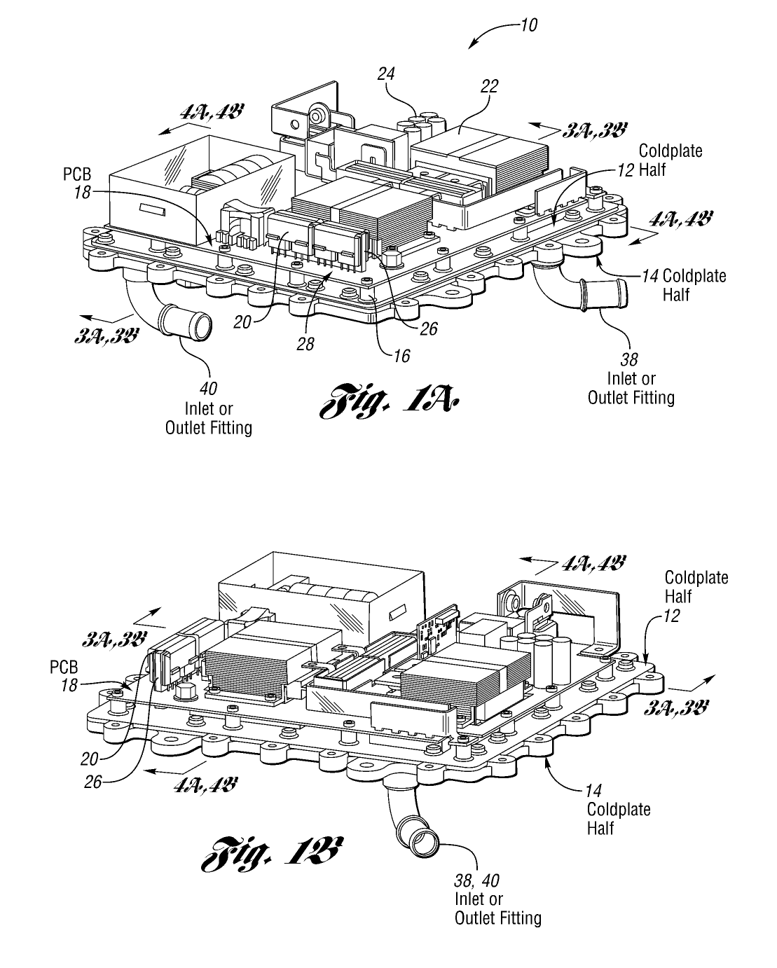

Referring now to FIGS. 1A and 1B, perspective views of a coldplate or heat sink for use in an electric vehicle (EV) or a hybrid-electric vehicle (HEV) are shown, denoted generally by reference numeral 10. As seen therein, the coldplate 10 may have a substantially plate-like shape, although other shapes may also be employed.

The coldplate 10 may comprise a first or upper portion 12 and a second or lower portion 14, each of which may be substantially plate-like in shape, although other shapes may alternatively be employed. The coldplate 10 and first and second portions 12, 14 may be manufactured from any suitable material and in any fashion know in the art. The first portion 12 may comprise multiple raised features 16 on a surface of the first portion 12. The raised features 16 may be configured for attaching the first portion 12 to a printed circuit board 18 having a plurality of electronic components attached thereto, such as metal-oxide-semiconductor field-effect transistors (MOSFET) 20, transformer 22, capacitors 24, and/or other components.

The coldplate 10 may also comprise one or more protrusions 26 extending from the surface of the first portion 12. The protrusions 26 may be configured for contacting one or more of the electronic components 20 attached to the printed circuit board 18 for dissipating heat generated by the one or more electronic components 20.

As seen in FIGS. 1A and 1B, the protrusions 26 may extend from the surface of the first portion 12 of the coldplate 10 and may be configured for contacting MOSFET 20 for dissipating heat generated by the MOSFET 20. In that regard, the printed circuit board 18 may be provided with one or more openings 28, and the protrusions 26 extending from the surface of the first portion 12 of the coldplate 10 may be configured for extending through the openings 28 formed in the printed circuit board 18. The openings 28 may be formed and aligned to facilitate cooperation between the protrusions 26 and corresponding electronic components 20.

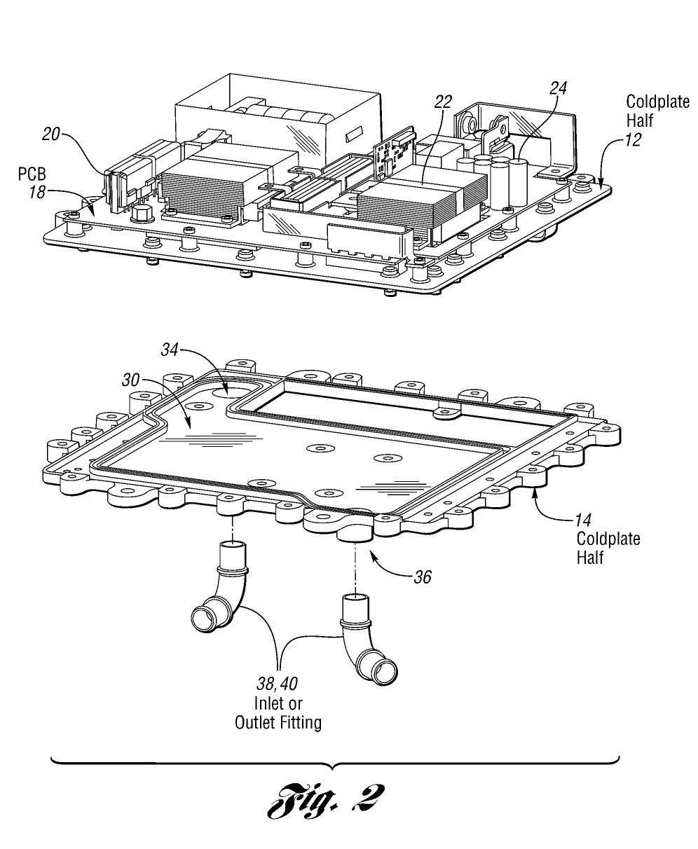

Referring now to FIG. 2, an exploded view of the coldplate 10 of FIGS. 1A and 1B is shown. As seen therein, and as previously discussed, the first portion 12 of the coldplate 10 may be configured for attachment to the printed circuit board 18, which may have a plurality of electronic components 20, 22, 24 thereon. The second portion 14 of the coldplate 10 may be configured for attachment to the first portion 12, and the second portion 14 may define a cavity 30.

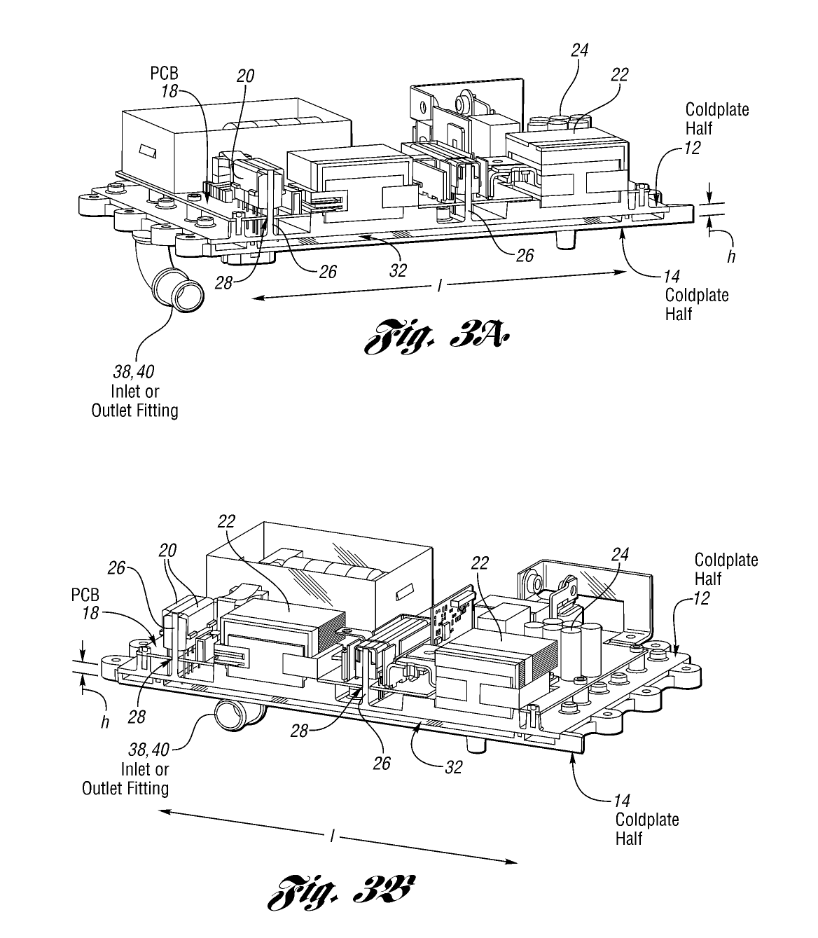

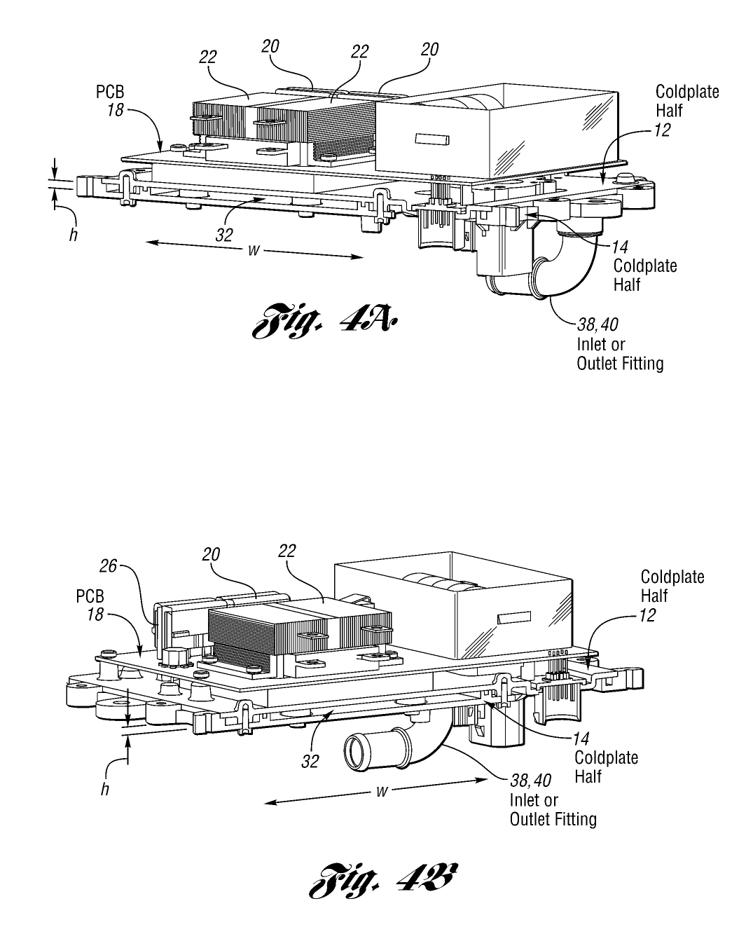

Referring next to FIGS. 3A, 3B, 4A and 4B, cross-sectional views of the coldplate of FIGS. 1A and 1B are shown. In that regard, the cross-sectional views shown in FIGS. 3A and 3B are taken along the lines 3A/3B-3A/3B in FIGS. 1A and 1B, and the cross-sectional views shown in FIGS. 4A and 4B are taken along the lines 4A/4B-4A/4B in FIGS. 1A and 1B.

As seen therein, and with continuing reference to FIG. 2, the first and second portions 12, 14 of the coldplate 10 may be further configured for attachment to each other to together form or define a manifold or chamber 32 therebetween. The manifold 32 may be provided with an inlet 34 and an outlet 36, which may be defined by the second portion 14 at a surface thereof, to provide for a flow of coolant (not shown) through the manifold 32 defined by the first and second portions 12, 14. The manifold 32 may also be provided with a substantially constant height, h, to facilitate a substantially uniform flow of a coolant therethrough for use in dissipating heat generated by the electronic components 20, 22, 24. In that regard, a coolant of any type known in the art may be circulated from the inlet 34 to the outlet 36 through the manifold or chamber 32 formed by the first and second portions 12, 14 of the coldplate 10. The inlet 34 and outlet 36 may be configured for attachment to inlet/outlet fittings 38, 40 for that purpose.

Still referring to FIGS. 3A, 3B, 4A and 4B, the attached first and second portions 12, 14 of the coldplate 10, together with the manifold or chamber 32 defined therebetween, have a substantially uniform cross section to facilitate a substantially uniform flow of a coolant (not shown) through the chamber 32 for use in dissipating heat generated by the electronic components 20, 22, 24. As seen therein, the manifold 32 has a height, h, that may be less than a width, w, and a length, l, of the manifold 32. In that regard, the height, h, of the manifold 32 may be substantially less than the width, w, and the length, l, which dimensions may be configured to provide coolant flow over a substantial or significant surface area of the first and/or second portions 12, 14 of the coldplate 10 in order to facilitate dissipation of heat generated by the electronic components 20, 22, 24 and absorbed by the coldplate 10.

As is readily apparent from the foregoing, a coldplate for use in an electric vehicle (EV) or a hybrid-electric vehicle (HEV) has been described. The embodiments of the coldplate described provide for additional heat dissipation beyond that which may be supplied by a standard coldplate used with an EV or HEV auxiliary power module. Such embodiments include a coldplate having a manifold or chamber for coolant flow through the coldplate, where the manifold or chamber is adapted to provide substantially uniform coolant flow through the coldplate for additional dissipation of heat generated by operation of electronic components of an auxiliary power module, thereby providing for efficient operation of the module.

While various embodiments of a coldplate for use in an electric vehicle (EV) or a hybrid-electric vehicle (HEV) have been illustrated and described herein, they are exemplary only and it is not intended that these embodiments illustrate and describe all those possible. Instead, the words used herein are words of description rather than limitation, and it is understood that various changes may be made to these embodiments without departing from the spirit and scope of the following claims.

What is claimed is:

1. A coldplate for use with electronic components in an electric vehicle (EV) or a hybrid-electric vehicle (HEV), the coldplate comprising:
a first portion configured for attachment to a printed circuit board having a plurality of electronic components thereon; and
a second portion configured for attachment to the first portion, wherein the first and second portions are further configured to together define a manifold therebetween, the manifold having an inlet, an outlet and a substantially constant height to facilitate a substantially uniform flow of a coolant therethrough for use in dissipating heat generated by the electronic components.

2. The coldplate of claim 1 wherein each of the first and second portions comprises a substantially plate-like member.

3. The coldplate of claim 2 wherein the height of the manifold defined by the first and second portions is less than a width and a length of the manifold.

4. The coldplate of claim 1 wherein the height of the manifold defined by the first and the second portions is less than a width and a length of the manifold.

5. The coldplate of claim 1 wherein the first portion has a protrusion extending from a surface thereof, the protrusion configured for contacting one of the plurality of electronic components attached to the printed circuit board for dissipating heat generated by the electronic component.

6. The coldplate of claim 5 wherein the protrusion extending from the surface of the first portion is oriented for substantial alignment with an opening formed in the printed circuit board.

7. The coldplate of claim 3 wherein the inlet and the outlet of the manifold defined by the first and second portions are defined by the second portion at a surface thereof.

8. A heat sink for use with electronic components in an electric vehicle (EV) or a hybrid-electric vehicle (HEV), the heat sink comprising:
a first portion configured for attachment to a printed circuit board having a plurality of electronic components thereon; and
a second portion configured for attachment to the first portion, wherein the first and second portions are further configured to together define a chamber therebetween, the attached first and second portions having a substantially uniform cross section to facilitate a substantially uniform flow of a coolant through the chamber for use in dissipating heat generated by the electronic components.

9. The heat sink of claim 8 wherein each of the first and second portions comprises a substantially plate-like member.

10. The heat sink of claim 9 wherein the chamber defined by the first and the second portions has a length, a width and a height, and the height of the chamber is less than the length and the width.

11. The heat sink of claim 8 wherein the chamber defined by the first and the second portions has a length, a width and a height, and the height of the chamber is less than the length and the width.

12. The heat sink of claim 8 wherein the first portion has a protrusion extending from a surface thereof, the protrusion configured for contacting one of the plurality of electronic components attached to the printed circuit board for dissipating heat generated by the electronic component.

13. The heat sink of claim 12 wherein the protrusion extending from the surface of the first portion is oriented for substantial alignment with an opening formed in the printed circuit board.

14. The heat sink of claim 8 further comprising an inlet and an outlet for coolant flow through the chamber, wherein the inlet and outlet are defined by the second portion at a surface thereof.

15. A heat sink for use with electronic components in an electric vehicle (EV) or a hybrid-electric vehicle (HEV), the heat sink comprising:
a first portion comprising a substantially plate-like member and configured for attachment to a printed circuit board having a plurality of electronic components thereon; and
a second portion comprising a substantially plate-like member and configured for attachment to the first portion, wherein the first and second portions are further configured to together define a chamber therebetween, the chamber having a substantially constant height to facilitate a substantially uniform flow of a coolant therethrough for use in dissipating heat generated by the electronic components.

16. The heat sink of claim 15 wherein the height of the chamber defined by the first and second portions is less than a width and a length of the chamber.

17. The heat sink of claim 16 wherein the height of the chamber is substantially less than the width and the length of the chamber.

18. The heat sink of claim 15 wherein the first portion has a protrusion extending from a surface thereof, the protrusion configured for contacting one of the plurality of electronic components attached to the printed circuit board for dissipating heat generated by the electronic component.

19. The heat sink of claim 18 wherein the protrusion extending from the surface of the first portion is oriented for substantial alignment with an opening formed in the printed circuit board.

20. The heat sink of claim 1 further comprising an inlet and an outlet for coolant flow through the chamber, wherein the inlet and outlet are defined by the second portion at a surface thereof.
